(19) United States
(12) Patent Application Publication
(10) Pub. No.: US 2019/0019471 A1
(43) Pub. Date: Jan. 17, 2019

(54) GATE DRIVER ON ARRAY CIRCUIT AND LIQUID CRYSTAL DISPLAY

(71) Applicant: Shenzhen China Star Optoelectronics Semiconductor Display Technology Co., Ltd., Shenzhen, Guangdong (CN)

(72) Inventor: Limei ZENG, Shenzhen, Guangdong (CN)

(73) Assignee: Shenzhen China Star Optoelectronics Semiconductor Display Technology Co., Ltd., Shenzhen, Guangdong (CN)

(21) Appl. No.: 15/739,727

(22) PCT Filed: Sep. 14, 2017
(86) PCT No.: PCT/CN2017/101669

§ 371 Date: Dec. 24, 2017

(30) Foreign Application Priority Data
Jul. 12, 2017 (CN) 201710566107.6

(51) Int. Cl. G09G 3/36; H01L 27/12; H01L 27/146; G02F 1/1368; G02F 1/133

(52) U.S. Cl. CPC G09G 3/3677; H01L 27/124; H01L 27/1225; H01L 27/14689; G09G 2310/08; G02F 1/13306; G09G 2310/0264; G09G 2300/0809; G02F 1/1368

(57) ABSTRACT

A GOA circuit applied in an LCD is provided. The GOA unit circuit includes cascaded GOA unit circuits. An Nth-stage GOA unit circuit includes a pull-up control circuit, a pull-up circuit, a downlink circuit, a bootstrap capacitance circuit, a pull-down holding circuit and a pull-down circuit. The pull-up control circuit couples to an (N−2)th-stage cascade signal and an (N−2)th-stage scanning signal. The pull-up circuit and the downlink circuit are connected a clock signal. The pull-down holding circuit couples to a first control signal. The pull-down circuit couples to an (N+2)th-stage cascade signal. By the GOA circuit, a set of pull-down holding circuit is adopted by the present disclosure, thereby reducing the number of transistors for use and further decreasing the difficulty in designing an LCD with a narrow bezel or without a bezel.

### 1. Field of the Disclosure

The present disclosure relates to the field of liquid crystal display (LCD), and more particularly, to a gate driver on array (GOA) circuit and an LCD.

### 2. Description of Related Art

Level scanning lines in an active LCD panel of the related art are driven (i.e., gate-driven) by an external integrated circuit (IC). The external IC is configured to supply voltage to a corresponding gate line to force a thin-film transistor (TFT) where the gate line corresponds to be turned on/off to drive the level scanning line at each stage completely. In the GOA technique, a driving circuit related to the level scanning line is fabricated on a non-display area of a substrate in a conventional manufacturing process of an LCD panel, which replaces the external IC. In this way, the driving of the level scanning line is still done without the external IC. With the GOA technique, the process of bonding of the external IC is simplified, which is very probable to increase the capacity and reduce the production cost.

Generally, two identical sets of pull-down holding circuit are adopted in the GOA unit circuit of the related art so a larger number of transistors are required and a larger area of a non-display area is needed, which is not good for a narrow bezel or bezel-less design.

### SUMMARY

A gate driver on array (GOA) circuit and a liquid crystal display (LCD) are proposed by the present disclosure. A set of pull-down holding circuit s are adopted in the GOA unit circuit and the LCD. In this way, the number of transistors for use decreases, and thereby, the difficulty in designing the LCD with a narrow bezel or without a bezel is reduced.

According to a first aspect of the present disclosure, a gate driver on array (GOA) circuit applied in a liquid crystal display (LCD) is provided. The GOA unit circuit comprises a plurality of cascaded GOA unit circuits. An Nth-stage GOA unit circuit comprises: a pull-up control circuit, configured to receive an (N−2)th-stage cascade signal and an (N−2)th-stage scanning signal and output an internal control signal at an Nth-stage gate signal node based on the (N−2)th-stage cascade signal and the (N−2)th-stage scanning signal; a pull-up circuit, configured to receive the internal control signal and a clock signal and pull up an Nth-stage scanning signal based on the internal control signal and the clock signal; a downlink circuit, configured to receive the internal control signal and the clock signal and output an Nth-stage cascade signal based on the internal control signal and the clock signal; a bootstrap capacitance circuit, configured to boost a high voltage level of the internal control signal; a pull-down holding circuit, configured to receive the internal control signal and a first control signal, and hold a low voltage level of the Nth-stage scanning signal based on the internal control signal and the first control signal; and a pull-down circuit, configured to receive the internal control signal and an (N+2)th-stage cascade signal and pull down the Nth-stage scanning signal based on the internal control signal and the (N+2)th-stage cascade signal. The pull-down holding circuit comprises a sixth transistor, a seventh transistor, an eighth transistor, a ninth transistor, a tenth transistor, and an eleventh transistor. A first terminal of the sixth transistor, a second terminal of the sixth transistor are electrically connected to a second terminal of the eighth transistor. The first terminal and the second terminal of the sixth transistor and the second terminal of the eighth transistor receive the first control signal. A third terminal of the sixth transistor is electrically connected to a second terminal of the seventh transistor and a first terminal of the eighth transistor; a first terminal of the seventh transistor is electrically connected to a first terminal of the ninth transistor. The two first terminals receive the internal control signal. A third terminal of the eighth transistor is electrically connected to a second terminal of the ninth transistor, a first terminal of the tenth transistor, and a first terminal of the eleventh transistor. A second terminal of the tenth transistor is connected to the Nth-stage scanning signal. A second terminal of the eleventh transistor is electrically connected to the Nth-stage gate signal node. A third terminal of the seventh transistor, a third terminal of the ninth transistor, a third terminal of the tenth transistor, and a third terminal of the eleventh transistor all are electrically connected to a low-voltage-level signal. The first control signal is a high-voltage-level signal. The pull-up control circuit comprises a first transistor. The first transistor comprises a first terminal receiving the (N−2)th-stage cascade signal, a second terminal receiving the (N−2)th-stage scanning signal, and a third terminal electrically connected to the Nth-stage gate signal node. The first transistor is configured to output the first control signal to the Nth-stage gate signal node.

According to a second aspect of the present disclosure, a gate driver on array (GOA) circuit applied in a liquid crystal display (LCD) is provided. The GOA unit circuit comprises a plurality of cascaded GOA unit circuits. An Nth-stage GOA unit circuit comprises: a pull-up control circuit, configured to receive an (N−2)th-stage cascade signal and an (N−2)th-stage scanning signal and output an internal control signal at an Nth-stage gate signal node based on the (N−2)th-stage cascade signal and the (N−2)th-stage scanning signal; a pull-up circuit, configured to receive the internal control signal and a clock signal and pull up an Nth-stage scanning signal based on the internal control signal and the clock signal; a downlink circuit, configured to receive the internal control signal and the clock signal and output an Nth-stage cascade signal based on the internal control signal and the clock signal; a bootstrap capacitance circuit, configured to boost a high voltage level of the internal control signal; a pull-down holding circuit, configured to receive the internal control signal and a first control signal, and hold a low voltage level of the Nth-stage scanning signal based on the internal control signal and the first control signal; and a pull-down circuit, configured to receive the internal control signal and an (N+2)th-stage cascade signal and pull down the Nth-stage scanning signal based on the internal control signal and the (N+2)th-stage cascade signal.

According to a third aspect of the present disclosure, a liquid crystal display comprising a gate driver on array (GOA) circuit is provided. The GOA unit circuit comprises a plurality of cascaded GOA unit circuits. An Nth-stage GOA unit circuit comprises: a pull-up control circuit, configured to receive an (N−2)th-stage cascade signal and an (N−2)th-stage scanning signal and output an internal control signal at an Nth-stage gate signal node based on the (N−2)th-stage cascade signal and the (N−2)th-stage scanning signal; a pull-up circuit, configured to receive the internal control signal and a clock signal and pull up an Nth-stage scanning signal based on the internal control signal and the clock signal; a downlink circuit, configured to receive the internal control signal and the clock signal and output an Nth-stage cascade signal based on the internal control signal and the clock signal; a bootstrap capacitance circuit, configured to boost a high voltage level of the internal control signal; a pull-down holding circuit, configured to receive the internal control signal and a first control signal, and hold a low voltage level of the Nth-stage scanning signal based on the internal control signal and the first control signal; and a pull-down circuit, configured to receive the internal control signal and an (N+2)th-stage cascade signal and pull down the Nth-stage scanning signal based on the internal control signal and the (N+2)th-stage cascade signal.

The beneficiary effect of the present disclosure is as follows. The GOA unit circuit and the LCD include a plurality of GOA unit circuits. The plurality of GOA unit circuits are cascaded. An Nth-stage GOA unit circuit includes a pull-up control circuit, a pull-up circuit, a downlink circuit, a bootstrap capacitance circuit, a pull-down holding circuit, and a pull-down circuit. The pull-up control circuit is configured to receive an (N−2)th-stage cascade signal and an (N−2)th-stage scanning signal to output an internal control signal at an Nth-stage gate signal node. The pull-up circuit is configured to receive the internal control signal and a clock signal to pull up an Nth-stage scanning signal. The downlink circuit is configured to receive the internal control signal and the clock signal to output an Nth-stage cascade signal. The bootstrap capacitance circuit is configured to raise the high voltage level of the internal control signal. The pull-down holding circuit is configured to receive the internal control signal and a first control signal to maintain the low voltage level of the Nth-stage scanning signal. The pull-down circuit is configured to receive the internal control signal and an (N+2)th-stage cascade signal to pull down the Nth-stage scanning signal. With the above-mentioned method, a set of pull-down holding circuit is adopted by the present disclosure, thereby reducing the number of transistors for use and further decreasing the difficulty in designing an LCD with a narrow bezel or without a bezel.

### BRIEF DESCRIPTION OF THE DRAWINGS

FIG. 1 is a schematic diagram of a gate driver on array (GOA) circuit according to a first embodiment of the present disclosure.

FIG. 2 is a circuit diagram of the GOA unit circuit 11 in the GOA circuit 10 illustrated in FIG. 1.

FIG. 3 illustrates a timing diagram of signals applied to the GOA unit circuit illustrated in FIG. 2.

FIG. 4 is a circuit diagram of a gate driver on array (GOA) circuit in a GOA unit circuit illustrated in FIG. 1 according to a second embodiment of the present disclosure.

FIG. 5 illustrates a timing diagram of the GOA unit circuit illustrated in FIG. 4. FIG. 6 is a schematic diagram of a liquid crystal display (LCD) according to a third embodiment of the present disclosure.

### DETAILED DESCRIPTION OF THE EMBODIMENTS

Embodiments of the present application are illustrated in detail in the accompanying drawings, in which like or similar reference numerals refer to like or similar elements or elements having the same or similar functions throughout the specification. The embodiments described below with reference to the accompanying drawings are exemplary and are intended to be illustrative of the present application, and are not to be construed as limiting the scope of the present application.

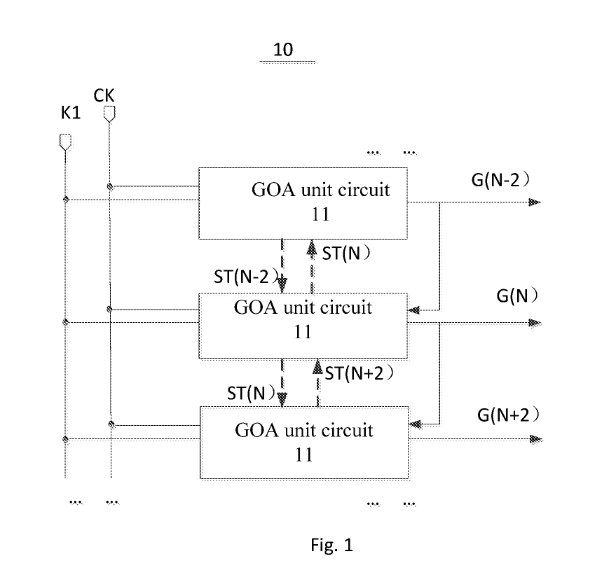

FIG. 1 is a schematic diagram of a gate driver on array (GOA) circuit 10 according to a first embodiment of the present disclosure. The GOA circuit 10 includes a plurality of GOA unit circuits 11. The plurality of GOA unit circuits 11 are cascaded.

An Nth-stage GOA unit circuit 11 is configured to output an Nth-stage scanning signal G(N) to correspond to an Nth level scanning line to charge the GOA circuit 10 under control of a clock signal CK, an (N−2)th-stage cascade signal ST(N−2), an (N+2)th-stage cascade signal ST(N+2), an (N−2)th-stage scanning signal G(N−2), and a first control signal K1. A transistor arranged in the GOA unit circuit is an indium gallium zinc oxide (IGZO) thin-film transistor (TFT).

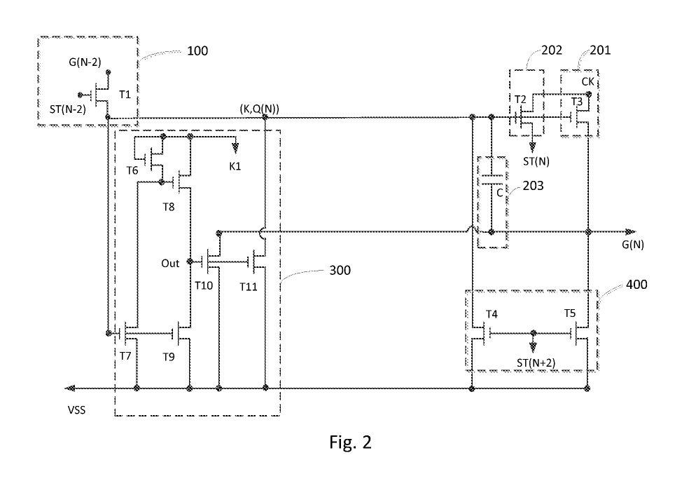

FIG. 2 is a circuit diagram of the GOA unit circuit 11 in the GOA circuit 10 illustrated in FIG. 1. As FIG. 2 illustrates, the Nth-stage GOA unit circuit 11 includes a pull-up control circuit 100, a pull-up circuit 201, a downlink circuit 202, a bootstrap capacitance circuit 203, a pull-down holding circuit 300, and a pull-down circuit 400.

The pull-up control circuit 100 is configured to receive the (N−2)th-stage cascade signal ST(N−2) and the (N−2)th-stage scanning signal G(N−2) and output an internal control signal K at an Nth-stage gate signal node Q(N) based on the (N−2)th-stage cascade signal ST(N−2) and the (N−2)th-stage scanning signal G(N−2).

The pull-up circuit 201 is configured to receive the internal control signal K and the clock signal CK and pull up the Nth-stage scanning signal G(N) based on the internal control signal K and the clock signal CK.

The downlink circuit 202 is configured to receive the internal control signal K and the clock signal CK and output an Nth-stage cascade signal ST(N) based on the internal control signal K and the clock signal CK.

The bootstrap capacitance circuit 203 is configured to boost the high voltage level of the internal control signal K.

The pull-down holding circuit 300 is configured to receive the internal control signal K and the first control signal K1 and maintain the low voltage level of the Nth-stage scanning signal G(N) based on the internal control signal K and the first control signal K1.

The pull-down circuit 400 is configured to receive the internal control signal K and the (N+2)th-stage cascade signal ST(N+2) and pull down the Nth-stage scanning signal G(N) based on the internal control signal K and the (N+2)th-stage cascade signal ST(N+2).

The pull-up control circuit 100 includes a first transistor T1. The first transistor T1 includes a first terminal receiving an (N−2)th-stage cascade signal ST(N−2), a second terminal receiving the (N−2)th-stage scanning signal G(N−2), and a third terminal electrically connected to the Nth-stage gate signal node Q(N). The first transistor T1 is configured to output the first control signal K to the Nth-stage gate signal node Q(N).

The pull-up circuit 201 includes a third transistor T3. The downlink circuit 202 includes a second transistor T2. The bootstrap capacitance circuit 203 includes a capacitor C.

A first terminal of the second transistor T2 is electrically connected to a first terminal of the third transistor T3. Afterwards, the two first terminals receive the internal control signal K. A second terminal of the second transistor T2 is electrically connected to a second terminal of the third transistor T3. Afterwards, the two second terminals receive the clock signal CK. A third terminal of the second transistor T2 outputs the Nth-stage cascade signal ST(N). A third terminal of the third transistor T3 is connected to the Nth-stage scanning signal G(N). The capacitor C includes two terminals electrically connected to the first terminal of the second transistor T2 and the third terminal of the third transistor T3 correspondingly.

The pull-down holding circuit 300 includes a sixth transistor T6, a seventh transistor T7, an eighth transistor T8, a ninth transistor T9, a tenth transistor T10, and an eleventh transistor T11. A first terminal of the sixth transistor T6 and a second terminal of the sixth transistor T6 are electrically connected to a second terminal of the eighth transistor T8. Afterwards, the first and second terminals of the sixth transistor T6 and the second terminal of the eighth transistor T8 receive the first control signal K1. A third terminal of the sixth transistor T6 is electrically connected to a second terminal of the seventh transistor T7 and a first terminal of the eighth transistor T8. A first terminal of the seventh transistor T7 is electrically connected to a first terminal of the ninth transistor T9. Afterwards, the two first terminals receive the internal control signal K. A third terminal of the eighth transistor T8 is electrically connected to a second terminal of the ninth transistor T9, a first terminal of the tenth transistor T10, and a first terminal of the eleventh transistor T11. A second terminal of the tenth transistor T10 is connected to the Nth-stage scanning signal G(N). A second terminal of the eleventh transistor T11 is electrically connected to the Nth-stage gate signal node Q(N). A third terminal of the seventh transistor T7, a third terminal of the ninth transistor T9, a third terminal of the tenth transistor T10, and a third terminal of the eleventh transistor T11 all are electrically connected to a low-voltage-level signal VSS.

The pull-down holding circuit 300 includes an inverter. An input terminal of the inverter is the Nth-stage gate signal node Q(N). An output terminal of the inverter is a common connecting terminal of the tenth transistor T10, a common connecting terminal of the eighth transistor T8, and a common connecting terminal of the ninth transistor T9. The output terminal of the inverter is called note Out.

The pull-down circuit 400 includes a fourth transistor T4 and a fifth transistor T5. A first terminal of the fourth transistor T4 is electrically connected to a first terminal of the fifth transistor T5. Afterwards, the two first terminals receive the (N+2)th-stage cascade signal ST(N+2). A second terminal of the fourth transistor T4 receives the internal control signal K. A second terminal of the fifth transistor T5 is connected to the Nth-stage scanning signal G(N). A third terminal of the fourth transistor T4 and a third terminal of the fifth transistor T5 both are electrically connected to the low-voltage-level signal VSS.

The control signal K1 is a high-voltage-level signal as well as a direct-current (DC) signal in the first embodiment.

In the first embodiment, the transistors from the first TFT T1 to the eleventh TFT T11 all are N-type metal-oxide-semiconductor (MOS) transistors. Besides, from the first terminal of the first transistor T1 to the first terminal of the eleventh transistor T11 all are gates of the N-type MOS transistor. The second terminals of the transistors from the first transistor T1 to the eleventh transistor T11 all are drains of the N-type MOS transistor. The third terminals of the transistors from the first transistor T1 to the eleventh transistor T11 all are sources of the N-type MOS transistor.

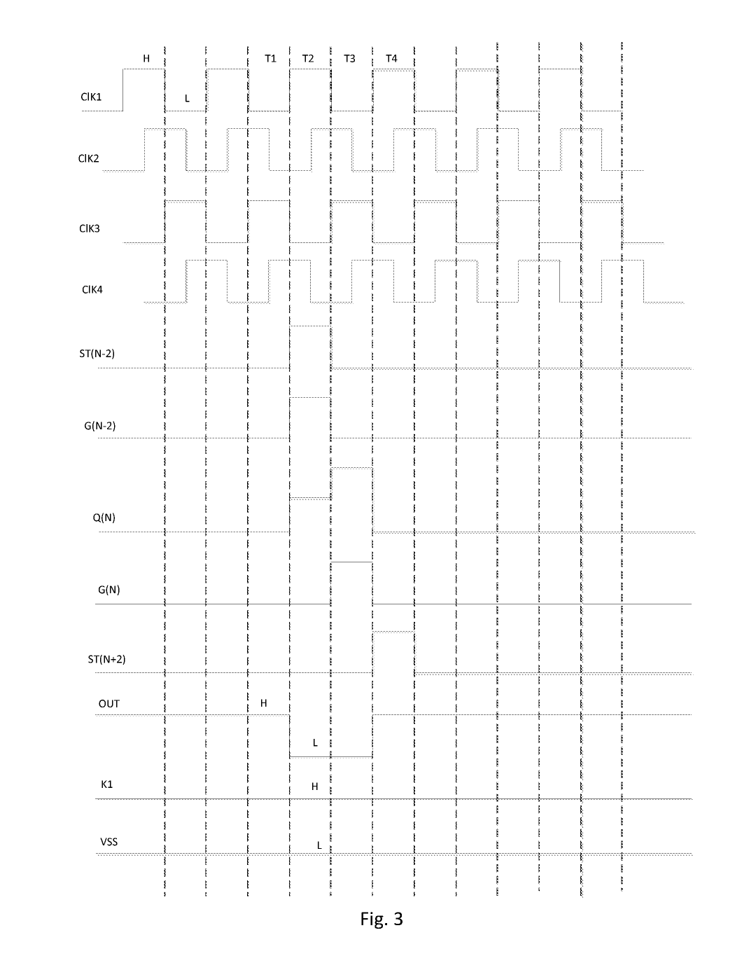

Please refer to FIG. 3 as well. FIG. 3 illustrates a timing diagram of signals applied to the GOA unit circuit illustrated in FIG. 2. As FIG. 3 illustrates, H indicates high voltage level, and L indicates low voltage level. The clock signal CK includes four clock signals. The four clock signals works on the four neighboring GOA unit circuits successively and circularly. The four clock signals are a first clock signal CLK1, a second clock signal CLK2, a third clock signal CLK3, and a fourth clock signal CLK4. When the clock signal CK is the first clock signal CLK1 and the third clock signal CLK3, the clock signal CK works on the odd-stage GOA unit circuits. When the clock signal CK is the second clock signal CLK2 and the fourth clock signal CLK4, the clock signal CK works on the even-stage GOA unit circuits. In this work timing diagram, the GOA unit circuit which the clock signal CK as the third clock signal CLK3 works on is introduced.

During the period of T1, the third clock signal CLK3 is at a high voltage level. The (N−2)th-stage cascade signal ST(N−2) and the (N−2)th-stage scanning signal G(N−2) both are at a low voltage level. The first transistor T1 is turned off. The Nth-stage gate signal node Q(N) stays at a low voltage level. The pull-up circuit 201 is disconnected. The Nth-stage scanning signal G(N) is at low voltage level signal.

During the period of T2, the third clock signal CLK3 is at a low voltage level. The (N−2)th-stage cascade signal ST(N−2) and the (N−2)th-stage scanning signal G(N−2) both are at a high voltage level. The first transistor T1 is turned on. The Nth-stage gate signal node Q(N) stays at a high voltage level. The capacitor C is charged. Meanwhile, the second transistor T2 and the third transistor T3 turn on. Because the third clock signal CLK3 is at a low voltage level, the Nth-stage scanning signal G(N) is at a low voltage level. The pull-down holding circuit 300 outputs low voltage level at the node OUT.

During the period of T3, the third clock signal CLK3 is at a high voltage level. The voltage imposed on the Nth-stage gate signal node Q(N) at the gate of the third transistor is raised to a higher voltage level because of the existence of the capacitor C (which has been charged). Because of the third clock signal CLK3 is at a high voltage level, the Nth-stage scanning signal G(N) is at high voltage level. A low-voltage-level signal is output through the node OUT in the pull-down holding circuit 300 continuously.

During the period of T4, the third clock signal CLK3 is at a low voltage level. The (N+2)th-stage cascade signal ST(N+2) is at high voltage level. The pull-down circuit 400 pulls down the voltage imposed on the Nth-stage gate signal node Q(N) to force the Nth-stage scanning signal G(N) to output a low voltage level.

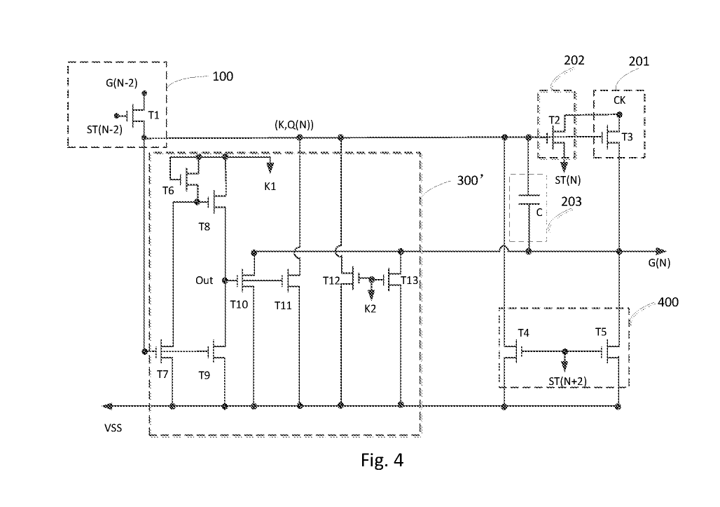

FIG. 4 is a circuit diagram of a gate driver on array (GOA) circuit in a GOA unit circuit illustrated in FIG. 1 according to a second embodiment of the present disclosure. The difference between the second embodiment as FIG. 4 illustrates and the first embodiment as FIG. 2 illustrates is that a pull-down holding circuit 300′ illustrated in FIG. 4 further includes a twelfth transistor T12 and a thirteenth transistor T13. A first terminal of the twelfth transistor T12 is electrically connected to a first terminal of the thirteenth transistor T13. Afterwards, the two first terminals receive a second control signal K2. A second terminal of the twelfth transistor T12 is electrically connected to an Nth-stage gate signal node Q(N). A second terminal of the thirteenth transistor T13 is electrically connected to a second terminal of a tenth transistor T10. A third terminal of the twelfth transistor T12 and a third terminal of the thirteenth transistor T13 both are electrically connected to a low-voltage-level signal VSS.

In the second embodiment, a first control signal K1 is a low-frequency signal, and a second control signal K2 is a high-frequency signal. In another embodiment, a second control signal K2 is an inverted signal of a clock signal CK of an Nth-stage gate driver on array (GOA) circuit, and the clock signal CK of the Nth-stage GOA unit circuit is an inverted signal of the second control signal K2.

The first control signal K1 in the GOA unit circuit illustrated in FIG. 2 is a high-voltage-level signal so the tenth transistor T10 and the eleventh transistor T11 bear the direct-current (DC) stress with the positive polarity voltage for a longer period of time. The threshold voltage of the tenth transistor T10 and the eleventh transistor T11 drifts to a greater scale after the tenth transistor T10 and the eleventh transistor T11 work for a long time, which results in the degradation of conductivity capability and further the damage of the lifespan of a pull-down transistor. In other words, the first control signal K1 at the high voltage level produces the stress effect on the tenth transistor T10 and the eleventh transistor T11, thereby affecting the lifespan of the tenth transistor T10 and the lifespan of the eleventh transistor T11. Therefore, the first control signal K1 in the GOA unit circuit illustrated in FIG. 4 is switched to the low-frequency signal to reduce the stress effect. Besides, a set of the twelfth transistor T12 and the thirteenth transistor T13 pulled down by the high-frequency signal (i.e., the second control signal K2) is added to ensure that the pull-down function of the pull-down holding circuit 300′ still works when the first control signal K1 is at the low voltage level.

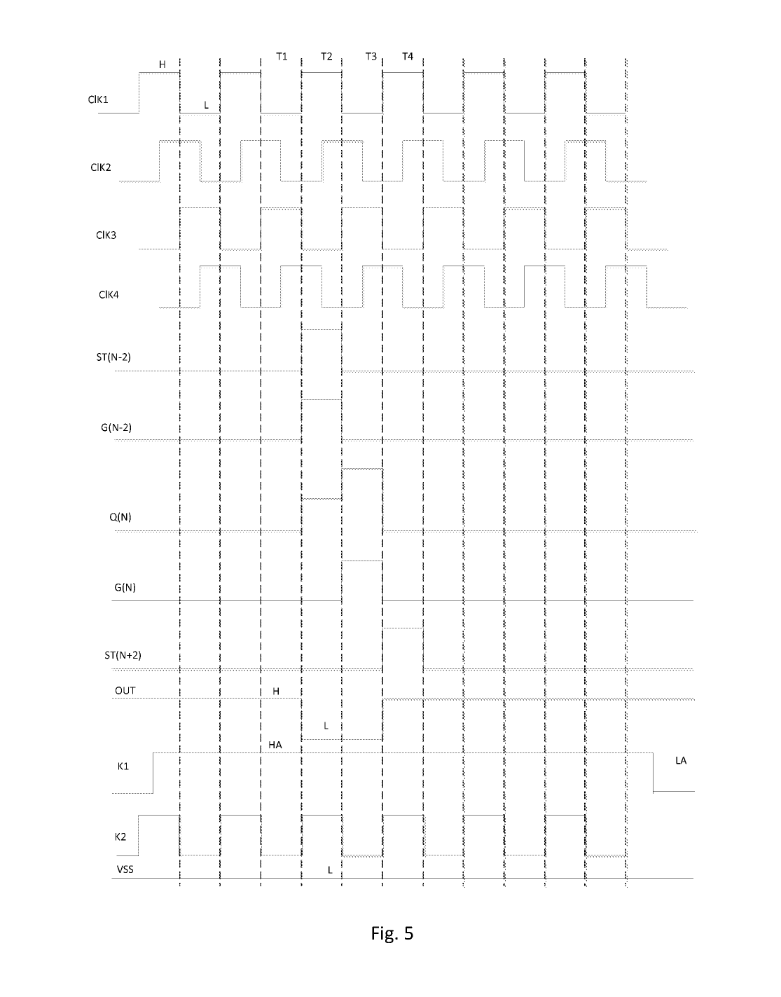

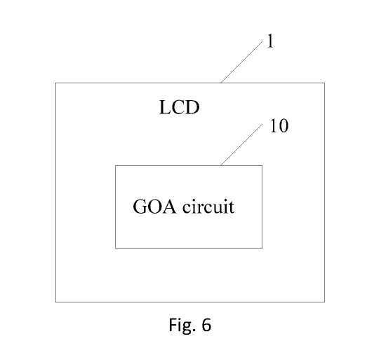

Please refer to FIG. 5 as well. FIG. 5 illustrates a timing diagram of the GOA unit circuit illustrated in FIG. 4. The difference between the timing diagram illustrated in FIG. 5 and the timing diagram illustrated in FIG. 3 is what is described as follows.

The first control signal K1 is the low-frequency signal in FIG. 5. The first control signal K1 is the high-frequency signal in FIG. 3. In addition, a second control signal K2 is added in FIG. 5. The second control signal K2 and the third clock signal CLK3 are inverted, and the third clock signal CLK3 and the second control signal K2 are inverted.

A set of the tenth transistor T10 and the eleventh transistor T11 with the lowest stress effect is obtained based on the setting of the volume of voltage of the first control signal K1 and the frequency of the first control signal K1.

The volume of the voltage indicates volume of a high-voltage-level voltage HA of the first control signal K1 and a low-voltage-level voltage LA of the first control signal K1. For example, the high-voltage-level voltage HA is 28 volts (V) and the low-voltage-level voltage LA is −8V. Or, the high-voltage-level voltage HA is 22 volts (V) and the low-voltage-level voltage LA is −6V.

The frequency indicates the frequency transformed between the high-voltage-level voltage HA and the low-voltage-level voltage LA. For example, the high-voltage-level voltage HA keeping 16.667 milliseconds (ms) (i.e., 100 frames) is transformed into the low-voltage-level voltage LA, and the low-voltage-level voltage LA keeps 100 frames and repeatedly circulates. Or, the high-voltage-level voltage HA keeping 50 frames is transformed into the low-voltage-level voltage LA, and the low-voltage-level voltage LA keeps 100 frames and repeatedly circulates.

FIG. 6 is a schematic diagram of the structure of a liquid crystal display (LCD) 1 according to a third embodiment of the present disclosure. The LCD 1 includes a gate driver on array (GOA) circuit 10 as introduced above.

The beneficiary effect of the present disclosure is as follows. The GOA unit circuit and the LCD include a plurality of GOA unit circuits. The plurality of GOA unit circuits are cascaded. An Nth-stage GOA unit circuit includes a pull-up control circuit, a pull-up circuit, a downlink circuit, a bootstrap capacitance circuit, a pull-down holding circuit, and a pull-down circuit. The pull-up control circuit is configured to receive an (N−2)th-stage cascade signal and an (N−2)th-stage scanning signal to output an internal control signal at an Nth-stage gate signal node. The pull-up circuit is configured to receive the internal control signal and a clock signal to pull up an Nth-stage scanning signal. The downlink circuit is configured to receive the internal control signal and the clock signal to output an Nth-stage cascade signal. The bootstrap capacitance circuit is configured to raise the high voltage level of the internal control signal. The pull-down holding circuit is configured to receive the internal control signal and a first control signal to maintain the low voltage level of the Nth-stage scanning signal. The pull-down circuit is configured to receive the internal control signal and an (N+2)th-stage cascade signal to pull down the Nth-stage scanning signal. With the above-mentioned method, a set of pull-down holding circuit is adopted by the present disclosure, thereby reducing the number of transistors for use and further decreasing the difficulty in designing an LCD with a narrow bezel or without a bezel.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

What is claimed is:

1. A gate driver on array (GOA) circuit applied in a liquid crystal display (LCD), the GOA unit circuit comprising a plurality of cascaded GOA unit circuits, wherein an Nth-stage GOA unit circuit comprises:
a pull-up control circuit, configured to receive an (N−2)th-stage cascade signal and an (N−2)th-stage scanning signal and output an internal control signal at an Nth-stage gate signal node based on the (N−2)th-stage cascade signal and the (N−2)th-stage scanning signal;
a pull-up circuit, configured to receive the internal control signal and a clock signal and pull up an Nth-stage scanning signal based on the internal control signal and the clock signal;
a downlink circuit, configured to receive the internal control signal and the clock signal and output an Nth-stage cascade signal based on the internal control signal and the clock signal;
a bootstrap capacitance circuit, configured to boost a high voltage level of the internal control signal;
a pull-down holding circuit, configured to receive the internal control signal and a first control signal, and hold a low voltage level of the Nth-stage scanning signal based on the internal control signal and the first control signal; and
a pull-down circuit, configured to receive the internal control signal and an (N+2)th-stage cascade signal and pull down the Nth-stage scanning signal based on the internal control signal and the (N+2)th-stage cascade signal,
wherein the pull-down holding circuit comprises a sixth transistor, a seventh transistor, an eighth transistor, a ninth transistor, a tenth transistor, and an eleventh transistor;
a first terminal of the sixth transistor, a second terminal of the sixth transistor are electrically connected to a second terminal of the eighth transistor; the first terminal and the second terminal of the sixth transistor and the second terminal of the eighth transistor receive the first control signal; a third terminal of the sixth transistor is electrically connected to a second terminal of the seventh transistor and a first terminal of the eighth transistor; a first terminal of the seventh transistor and a first terminal of the ninth transistor receive the internal control signal; a third terminal of the eighth transistor is electrically connected to a second terminal of the ninth transistor, a first terminal of the tenth transistor, and a first terminal of the eleventh transistor; a second terminal of the tenth transistor is connected to the Nth-stage scanning signal; a second terminal of the eleventh transistor is electrically connected to the Nth-stage gate signal node; a third terminal of the seventh transistor, a third terminal of the ninth transistor, a third terminal of the tenth transistor, and a third terminal of the eleventh transistor all are electrically connected to a low-voltage-level signal,
wherein the first control signal is a high-voltage-level signal,
wherein the pull-up control circuit comprises a first transistor; the first transistor comprises a first terminal receiving the (N−2)th-stage cascade signal, a second terminal receiving the (N−2)th-stage scanning signal, and a third terminal electrically connected to the Nth-stage gate signal node; the first transistor is configured to output the first control signal to the Nth-stage gate signal node.

2. The GOA circuit of claim 1, wherein the pull-up circuit comprises a third transistor; the downlink circuit comprises a second transistor; the bootstrap capacitance circuit comprises a capacitor;
a first terminal of the second transistor and a first terminal of the third transistor receive the internal control signal; a second terminal of the second transistor and a second terminal of the third transistor receive the clock signal; a third terminal of the second transistor outputs the Nth-stage cascade signal; a third terminal of the third transistor is connected to the Nth-stage scanning signal;
the capacitor comprises two terminals electrically connected to the first terminal of the second transistor and the third terminal of the third transistor correspondingly.

3. A gate driver on array (GOA) circuit applied in a liquid crystal display (LCD), the GOA unit circuit comprising a plurality of cascaded GOA unit circuits, wherein an Nth-stage GOA unit circuit comprises:
a pull-up control circuit, configured to receive an (N−2)th-stage cascade signal and an (N−2)th-stage scanning signal and output an internal control signal at an Nth-stage gate signal node based on the (N−2)th-stage cascade signal and the (N−2)th-stage scanning signal;
a pull-up circuit, configured to receive the internal control signal and a clock signal and pull up an Nth-stage scanning signal based on the internal control signal and the clock signal;
a downlink circuit, configured to receive the internal control signal and the clock signal and output an Nth-stage cascade signal based on the internal control signal and the clock signal;
a bootstrap capacitance circuit, configured to boost a high voltage level of the internal control signal;
a pull-down holding circuit, configured to receive the internal control signal and a first control signal, and hold a low voltage level of the Nth-stage scanning signal based on the internal control signal and the first control signal; and
a pull-down circuit, configured to receive the internal control signal and an (N+2)th-stage cascade signal and pull down the Nth-stage scanning signal based on the internal control signal and the (N+2)th-stage cascade signal.

4. The GOA circuit of claim 3, wherein the pull-down holding circuit comprises a sixth transistor, a seventh transistor, an eighth transistor, a ninth transistor, a tenth transistor, and an eleventh transistor;
a first terminal of the sixth transistor, a second terminal of the sixth transistor are electrically connected to a second terminal of the eighth transistor; the first terminal and the second terminal of the sixth transistor and the second terminal of the eighth transistor receive the first control signal; a third terminal of the sixth transistor is electrically connected to a second terminal of the seventh transistor and a first terminal of the eighth transistor; a first terminal of the seventh transistor and a first terminal of the ninth transistor receive the internal control signal; a third terminal of the eighth transistor is electrically connected to a second terminal of the ninth transistor, a first terminal of the tenth transistor, and a first terminal of the eleventh transistor; a second terminal of the tenth transistor is connected to the Nth-stage scanning signal; a second terminal of the eleventh transistor is electrically connected to the Nth-stage gate signal node; a third terminal of the seventh transistor, a third terminal of the ninth transistor, a third terminal of the tenth transistor, and a third terminal of the eleventh transistor all are electrically connected to a low-voltage-level signal.

5. The GOA circuit of claim 4, wherein the first control signal is a high-voltage-level signal.

6. The GOA circuit of claim 4, wherein the pull-down holding circuit further comprises a twelfth transistor and a thirteenth transistor when the first control signal is a low-frequency signal;
a first terminal of the twelfth transistor and a first terminal of the thirteenth transistor receive a second control signal; a second terminal of the twelfth transistor is electrically connected to an Nth-stage gate signal node; a second terminal of the thirteenth transistor is electrically connected to a second terminal of a tenth transistor; a third terminal of the twelfth transistor and a third terminal of the thirteenth transistor both are electrically connected to the low-voltage-level signal.

7. The GOA circuit of claim 6, wherein the second control signal is an inverted signal of the clock signal of the Nth-stage unit, and the clock signal of the Nth-stage unit is an inverted signal of the second control signal.

8. The GOA circuit of claim 4, wherein the pull-up control circuit comprises a first transistor; the first transistor comprises a first terminal receiving the (N−2)th-stage cascade signal, a second terminal receiving the (N−2)th-stage scanning signal, and a third terminal electrically connected to the Nth-stage gate signal node; the first transistor is configured to output the first control signal to the Nth-stage gate signal node.

9. The GOA circuit of claim 8, wherein the pull-up circuit comprises a third transistor; the downlink circuit comprises a second transistor; the bootstrap capacitance circuit comprises a capacitor;
a first terminal of the second transistor and a first terminal of the third transistor receive the internal control signal; a second terminal of the second transistor and a second terminal of the third transistor receive the clock signal; a third terminal of the second transistor outputs the Nth-stage cascade signal; a third terminal of the third transistor is connected to the Nth-stage scanning signal;
the capacitor comprises two terminals electrically connected to the first terminal of the second transistor and the third terminal of the third transistor correspondingly.

10. The GOA circuit of claim 9, wherein the pull-down circuit comprises a fourth transistor and a fifth transistor;
a first terminal of the fourth transistor and a first terminal of the fifth transistor receive the (N+2)th-stage cascade signal; a second terminal of the fourth transistor receives the internal control signal; a second terminal of the fifth transistor is connected to the Nth-stage scanning signal; a third terminal of the fourth transistor and a third terminal of the fifth transistor both are electrically connected to the low-voltage-level signal.

11. The GOA circuit of claim 10, wherein the first transistor to the eleventh transistor all are N-type metal-oxide-semiconductor (MOS) transistors; the first terminal of the first transistor to the first terminal of the eleventh transistor all are gates of the N-type MOS transistors; the second terminal of the first transistor to the second terminal of the eleventh transistor all are drains of the N-type MOS transistors; the third terminal of the first transistor to the third terminal of the eleventh transistor all are sources of the N-type MOS transistors.

12. A liquid crystal display comprising a gate driver on array (GOA) circuit, the GOA unit circuit comprising a plurality of cascaded GOA unit circuits, wherein an Nth-stage GOA unit circuit comprises:
a pull-up control circuit, configured to receive an (N−2)th-stage cascade signal and an (N−2)th-stage scanning signal and output an internal control signal at an Nth-stage gate signal node based on the (N−2)th-stage cascade signal and the (N−2)th-stage scanning signal;
a pull-up circuit, configured to receive the internal control signal and a clock signal and pull up an Nth-stage scanning signal based on the internal control signal and the clock signal;
a downlink circuit, configured to receive the internal control signal and the clock signal and output an Nth-stage cascade signal based on the internal control signal and the clock signal;
a bootstrap capacitance circuit, configured to boost a high voltage level of the internal control signal;
a pull-down holding circuit, configured to receive the internal control signal and a first control signal, and hold a low voltage level of the Nth-stage scanning signal based on the internal control signal and the first control signal; and
a pull-down circuit, configured to receive the internal control signal and an (N+2)th-stage cascade signal and pull down the Nth-stage scanning signal based on the internal control signal and the (N+2)th-stage cascade signal.

13. The liquid crystal display of claim 12, wherein the pull-down holding circuit comprises a sixth transistor, a seventh transistor, an eighth transistor, a ninth transistor, a tenth transistor, and an eleventh transistor;
a first terminal of the sixth transistor, a second terminal of the sixth transistor are electrically connected to a second terminal of the eighth transistor; the first terminal and the second terminal of the sixth transistor and the second terminal of the eighth transistor receive the first control signal; a third terminal of the sixth transistor is electrically connected to a second terminal of the seventh transistor and a first terminal of the eighth transistor; a first terminal of the seventh transistor and a first terminal of the ninth transistor receive the internal control signal; a third terminal of the eighth transistor is electrically connected to a second terminal of the ninth transistor, a first terminal of the tenth transistor, and a first terminal of the eleventh transistor; a second terminal of the tenth transistor is connected to the Nth-stage scanning signal; a second terminal of the eleventh transistor is electrically connected to the Nth-stage gate signal node; a third terminal of the seventh transistor, a third terminal of the ninth transistor, a third terminal of the tenth transistor, and a third terminal of the eleventh transistor all are electrically connected to a low-voltage-level signal.

14. The liquid crystal display of claim 13, wherein the first control signal is a high-voltage-level signal.

15. The liquid crystal display of claim 13, wherein the pull-down holding circuit further comprises a twelfth transistor and a thirteenth transistor when the first control signal is a low-frequency signal;
a first terminal of the twelfth transistor and a first terminal of the thirteenth transistor receive a second control signal; a second terminal of the twelfth transistor is electrically connected to an Nth-stage gate signal node; a second terminal of the thirteenth transistor is electrically connected to a second terminal of a tenth transistor; a third terminal of the twelfth transistor and a third terminal of the thirteenth transistor both are electrically connected to the low-voltage-level signal.

16. The liquid crystal display of claim 15, wherein the second control signal is an inverted signal of the clock signal of the Nth-stage unit, and the clock signal of the Nth-stage unit is an inverted signal of the second control signal.

17. The liquid crystal display of claim 13, wherein the pull-up control circuit comprises a first transistor; the first transistor comprises a first terminal receiving the (N−2)th-stage cascade signal, a second terminal receiving the (N−2)th-stage scanning signal, and a third terminal electrically connected to the Nth-stage gate signal node; the first transistor is configured to output the first control signal to the Nth-stage gate signal node.

18. The liquid crystal display of claim 17, wherein the pull-up circuit comprises a third transistor; the downlink circuit comprises a second transistor; the bootstrap capacitance circuit comprises a capacitor;
a first terminal of the second transistor and a first terminal of the third transistor receive the internal control signal; a second terminal of the second transistor and a second terminal of the third transistor receive the clock signal; a third terminal of the second transistor outputs the Nth-stage cascade signal; a third terminal of the third transistor is connected to the Nth-stage scanning signal;
the capacitor comprises two terminals electrically connected to the first terminal of the second transistor and the third terminal of the third transistor correspondingly.

19. The liquid crystal display of claim 18, wherein the pull-down circuit comprises a fourth transistor and a fifth transistor;
a first terminal of the fourth transistor and a first terminal of the fifth transistor receive the (N+2)th-stage cascade signal; a second terminal of the fourth transistor receives the internal control signal; a second terminal of the fifth transistor is connected to the Nth-stage scanning signal; a third terminal of the fourth transistor and a third terminal of the fifth transistor both are electrically connected to the low-voltage-level signal.

20. The liquid crystal display of claim 19, wherein the first transistor to the eleventh transistor all are N-type metal-oxide-semiconductor (MOS) transistors; the first terminal of the first transistor to the first terminal of the eleventh transistor all are gates of the N-type MOS transistors; the second terminal of the first transistor to the second terminal of the eleventh transistor all are drains of the N-type MOS transistors; the third terminal of the first transistor to the third terminal of the eleventh transistor all are sources of the N-type MOS transistors.
